(19) United States
(12) Patent Application Publication
(10) Pub. No.: US 2012/0237695 A1
(43) Pub. Date: Sep. 20, 2012

(54) METHOD AND APPARATUS FOR DEPOSITING A THIN FILM

(75) Inventors: Thomas Pye, Santa Cruz, CA (US); Larry Bartholomew, Felton, CA (US)

(73) Assignee: 2-Pye Solar, LLC, Johns Creek, GA (US)

(21) Appl. No.: 13/427,864

(22) Filed: Mar. 22, 2012

Related U.S. Application Data
(63) Continuation-in-part of application No. 12/646,232, filed on Dec. 23, 2009, now abandoned.

(51) Int. Cl. C23C 16/46; C08J 7/18

(52) U.S. Cl. 427/554; 118/725; 427/557

(57) ABSTRACT

A substrate is brought into close proximity with one or more gas injectors to deposit a thin film. As the substrate is moved horizontally along a predefined direction, it is injected with reactive gases and pyrolytically heated with a heating light focused on the substrate. To prevent photolytic reactions, the heating light source is preferably on the side of the substrate opposite to the side where the reactive gases are deposited. In some embodiments, this heating light source is supplemented by heating light sources on the same side of the substrate as the deposited reactive gases. The heating light source(s) has a wavelength to optimize absorption by the substrate or the deposited film layer.

### CROSS-REFERENCED TO RELATED APPLICATIONS

This application is a continuation-in-part of U.S. application Ser. No. 12/646,232, filed on Dec. 23, 2009, the disclosures of which are incorporated herein by reference in their entirety for all purposes.

### FIELD OF THE INVENTION

The present invention relates to the field of thin film deposition and, more particularly, to atmospheric pressure deposition of thin films in an open in-line system during the manufacture of photovoltaic, semiconductor, opto-electronic, integrated circuit devices, and the like.

### BACKGROUND OF THE INVENTION

The continuing rise in demand for energy, coupled with concerns about consequences of the increasing level of carbon dioxide in the atmosphere, has resulted in a drive to explore and harness alternative and renewable sources of energy. The supply of fossil fuels, such as oil and coal, is limited and will not be sufficient to meet the ever rising demand for this source of energy. Alternative sources of energy must be developed before the Earth is depleted of its limited supply of fossil fuel.

Environmentally clean and renewable sources of energy include hydroelectric, wind, and solar power. Hydroelectric power is produced by electric generators driven by the flow of water. Windmills transform wind energy into electricity. Solar power generation transforms the radiation energy of the sun to electrical energy. A photovoltaic solar cell may be fabricated on a semiconductor wafer using semiconductor processing technology to form a p-n junction. Solar radiation impinging on the solar cell generates electron hole pairs that migrate to the p and n regions, thereby creating voltage differentials between these two regions.

Many limitations remain to be resolved before environmentally clean solar power production using photovoltaic cells becomes competitive with existing power generation plants and thus economically viable for widespread use. Photovoltaic solar cells made from crystalline materials often have better rates of converting electromagnetic radiation into electrical power and better reliability than those made with conventional thin film technology, but are often costly and difficult to manufacture on a large scale. For example, crystalline silicon is well established and characterized as a reliable photovoltaic absorber material, but many techniques attempting to manufacture a thin film version of a silicon solar cell to reduce material costs suffer from poorer energy conversion efficiency that does not yield a cost benefit. Thus, a thin film deposition technique that approaches the quality of the bulk crystalline material in a cost-effective thin film form could yield a photovoltaic solar cell competitive with existing power generation plants.

Many applications of thin film deposition require a high deposition rate to be commercially viable. Chemical reaction rates increase with temperature and are generally not the limiting factor to achieve a high deposition rate versus other constraints in controlling the fast reaction. Additionally, desirable material properties are often only achieved by utilizing a sufficiently high temperature for a complete chemical reaction either during deposition or in a subsequent annealing process. A reaction driven by the temperature of the substrate can yield high quality films on the desired surface and avoid some of the issues and complication associated with supplying alternative forms of energy such as a plasma to activate the process at a lower substrate temperature. Extremely rapid deposition rates by thermal pyrolysis exceeding tens of microns per second have been demonstrated in a controlled fashion in a small spot typically less than 1 mm² utilizing a focused energy beam such as a laser to heat the substrate surface for direct write applications or fiber generation. However, current thermal deposition technology suffers from uncontrolled reaction on all exposed surfaces or parasitic reaction in the gas phase yielding poor film quality with rapid depletion degrading uniformity when attempting to cover large substrate areas as the deposition rate is increased with temperature or chemical concentration. Using plasma or photolytic interaction to activate the reaction in the gas phase at a lower substrate temperature suffers the same problems when attempting to increase the deposition rate significantly.

Limitations to existing thin film deposition technology have so far made it economically impractical to generate production volume quantities of a silicon absorber film having near crystalline quality in a thin film form to yield unsubsidized competitive photovoltaic solar cells. Silicon films for photovoltaic applications are just one example where a new technology for thin film deposition could yield significant benefits.

### SUMMARY OF THE INVENTION

The present invention provides an energy and reagent efficient method of forming a thin film on the surface of a substrate in an open in-line system. One embodiment of the present invention includes positioning a first gas injector in close proximity to the substrate, injecting a reactive gas from the gas injector to a predefined surface area of the substrate, and concurrently applying at least a first heating light beam to provide heat to the side of the substrate opposite from the side where deposition of reactive gases takes place. In other words, in this preferred embodiment, where the reactive gases are deposited on top of the substrate, heat is preferably provided from below the substrate. In the case that the reactive gases are supplied to react on the bottom of the substrate, heat is preferably provided from above the substrate.

In several preferred thin film deposition methods of the present invention, only the substrate is heated, which in turn provides the energy for thermal pyrolysis of the reactant gases to form the deposited film as they contact the substrate. The substrate is heated to a temperature desirable for large scale commercial production deposition rates and film properties. By heating only the substrate, reaction in the gas phase and on surrounding surfaces is minimized. This has the beneficial effect of significantly extending the capability of existing equipment for higher deposition rates and throughput while minimizing down time for cleaning.

Further, the focused pyrolytic deposition method of the present invention will allow uniform large area deposition of silicon absorber films at high temperature and high deposition rate yielding high throughput of near crystalline quality in a cold-wall system where the reaction is limited to the hot substrate rather than depositing everywhere and depleting non-uniformly with uncontrolled gas phase reaction. Other films suitable as additional layers in a photovoltaic solar cell, such as barrier, passivation or anti-reflective coatings may also be deposited using additional embodiments of the present invention. These films may be deposited, for example, in sequence in one open, in-line system. The methods of the present invention are not only applicable in photovoltaics, but also for semiconductors, opto-electronic, integrated circuit and other applications.

In a further embodiment, the method includes concurrent application of a second and/or third light beam, this time to the same side of the substrate as the reactive gas in order to provide additional heat for pyrolytic deposition of the film.

In some embodiments of the invention, the substrate moves at a substantially constant speed relative to the injector to achieve continuous deposition of the same thickness of the film over an entire surface area of the substrate. This process for moving the substrate also works with multiple gas injectors. For example, the substrate can be moved at a substantially constant speed relative to the first gas injector while also positioning the substrate in close proximity to a second gas injector, followed by injecting a second reactive gas from the second gas injector to the surface of the substrate, and applying a second light beam to the opposite side of the substrate to provide heat for pyrolytic deposition of a second film on the substrate surface. This process can then be continued for further reactive gas injectors and light beams (e.g., third, fourth, fifth etc.).

In one embodiment, the first and second films described are the same materials. In another embodiment, the first and second films include different materials. In some embodiments, the light beams have a wavelength(s) selected so the light energy will be absorbed substantially either by the substrate or the film. The injection of the first gas and the applying of the first light beam are preferably performed at or near atmospheric pressure. Also, in some embodiments, the second light beam is used to anneal the deposited film.

An open in-line system adapted to deposit a thin film on a surface of a substrate, in accordance with one embodiment of the present invention, includes a substrate holder adapted to hold the substrate, a first gas injector adapted to inject at least one reactive gas to a predefined surface area of the substrate, and a first light source adapted to concurrently apply a first light beam to the opposite side of the substrate in order to provide heat for pyrolytic deposition of a first film on the predefined surface area on the substrate, the first film including an element carried by the reactive gas.

### BRIEF DESCRIPTION OF THE DRAWINGS

FIG. 1 is a cross-sectional view of a thin film deposition system in accordance with one exemplary embodiment of the present invention.

FIG. 2 shows a number of chamber assemblies of a thin film deposition system in accordance with another exemplary embodiment of the present invention.

FIG. 3 is a cross-sectional view of one of the chamber assemblies of the FIG. 2 system.

FIG. 4 is a magnified perspective view of one of the chamber assemblies of the FIG. 2 system.

FIG. 5 shows a magnified perspective view of the deposition area of one of the chamber assemblies of the FIG. 2 system.

FIG. 6 is a flowchart of steps performed to deposit a thin film in accordance with one exemplary embodiment of the present invention.

FIG. 7 shows the power required to heat a 50 μm nickel foil substrate to 950° C. and maintain it at that temperature for 3 minutes for deposition within one of the chamber assemblies of the FIG. 2 system as calculated by a numerical model simulation.

### DETAILED DESCRIPTION OF THE INVENTION

In accordance with one embodiment of the present invention, a thin film or a multitude of film layers are deposited on a substrate by injecting chemical gases directly and locally on the surface of the substrate while the substrate surface is locally heated by a light beam applied to the opposite surface of the substrate. In other words, if the chemical gases are deposited on top of the substrate, heat is applied by a light beam situated under the substrate (or vice-versa). In this embodiment, the objective is to have the chemical deposition occur by thermal pyrolysis rather than photolytic interaction.

In some embodiments, the substrate is moved at a constant speed relative to a line source injecting the chemical gas. Film deposition may be carried out at or near atmospheric pressure in a chamber that is purged using an inert gas. Continuous processing in an open in-line system may be carried out in a controlled atmosphere using inert gas purge for isolation from ambient. Because of this isolation, deposition of metal or nitride films is feasible without oxygen. Thus, the system of the present invention is not limited to oxide films.

Each line source injector which injects a reactive chemical gas, together with its light beam, form a deposition zone. The localized heating of the substrate or film by the light beam allows much higher deposition temperature without uncontrolled reaction in the gas phase and on all chamber surfaces than is otherwise feasible. Uncontrolled reaction results in parasitic gas phase reaction causing detrimental particle incorporation and non-uniformity due to rapid reactive gas depletion at high reaction rates. The combination of high surface temperature and high partial pressure of chemical gases (also referred to herein as reactants) yields high deposition rates. To further enhance system throughput, several chambers may be used sequentially. The use of inert gas flows at slightly higher than atmospheric pressure at the input and output of the system, coupled with short diffusion lengths at atmospheric pressure, function as isolation curtains so that no external atmosphere contaminates the deposition regions. This allows a system configuration without sealed entry and exit load locks, where the substrates can be continually serially transported into, through, and out of each deposition area and finally exit the system. This is hereafter referred to as an open in-line system. The following description of the embodiments of the present invention is provided with reference to forming a thin film for use in a photovoltaic solar cell or a solar panel. It is understood, however, that the embodiments of the present invention are equally applicable to deposition of thin films for forming thin film displays, integrated circuits, semiconductors, opto-electronic devices and the like.

In some embodiments, multiple deposition zones may be used to form multiple film layers of the same chemical composition on the substrate for added thickness. In yet other embodiments, each deposition zone is used to deposit a thin layer of a different chemical composition. Higher quality films can be obtained at the high surface deposition temperature. Furthermore, in-situ incorporation of different dopants can be performed in the desired layers of the deposited films. Light beam annealing of the deposited layers can also be done between multiple deposition zones to modify the crystalline structure or activate the dopant in specific layers. In some embodiments, multiple light beams can be applied to heat the same surface of the substrate either to provide additional heat for pyrolytic deposition, to simultaneously apply heat to both sides of the substrate to minimize thermal stress and warpage, or to anneal the film to an even higher temperature than used for deposition.

The open atmospheric architecture, in accordance with one embodiment of the present invention, eliminates the need for expensive vacuum pumps and thus allows continuous processing of substrates without any interruptions that would otherwise result from vacuum load-locks. Use of purified gases yields extremely low contamination levels. The short mean free path of gas molecules at atmospheric pressure prevents external contaminants from entering into the deposition zone. U.S. Pat. No. 4,834,020, the content of which is incorporated herein by reference in its entirety, discloses an open system for depositing non-oxide film.

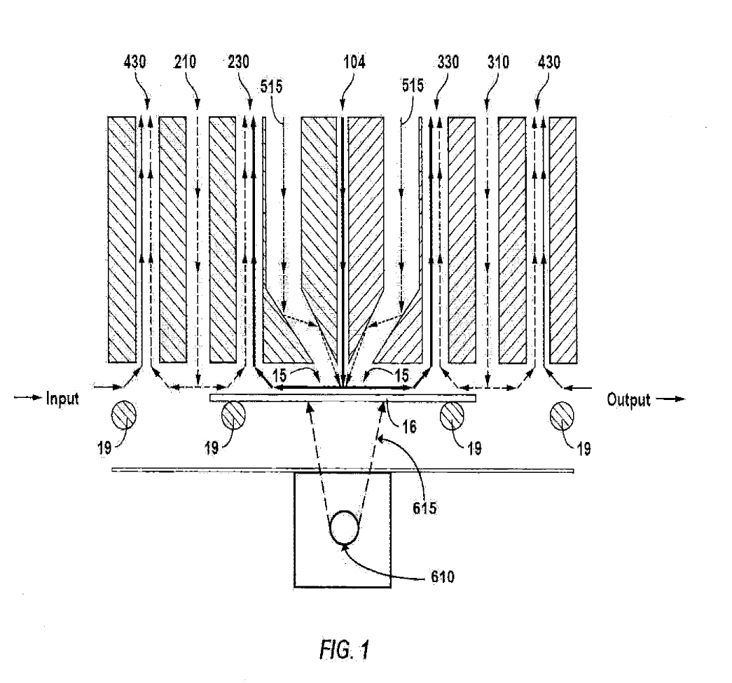

FIG. 1 is a simplified view of a deposition zone of an open in-line system adapted to deposit a thin film in accordance with one exemplary embodiment of the present invention. It is understood that this system may include more deposition zones as described further below. The reactive gas is injected onto the surface of substrate 16 through port 104. The gas flow splits and is exhausted in both directions of the split through ports 230 and 330. The light source 610, which serves as the primary heat source, applies light beam 615 underneath the substrate 16. In other words, in this embodiment, heat is primarily provided to a surface of the substrate 16 which is opposite to the surface the chemicals are deposited on. Additional light beams 515 may be applied to the top of the substrate surface 16 where the reactive gas is directed within deposition zone 15. On either side of the exhaust paths 230 and 330 are additional isolation gas sources 210 and 310 which part at the surface and are exhausted through ports 230, 330 and 430. The isolation gases 210 and 310 are used to block any external atmospheric contamination from entering the deposition zone 15. The light paths and gas paths are extended across the width of the substrate 16. The substrate 16 is transported from the input to the output by a conveyor roller 19 or other similar conveyance.

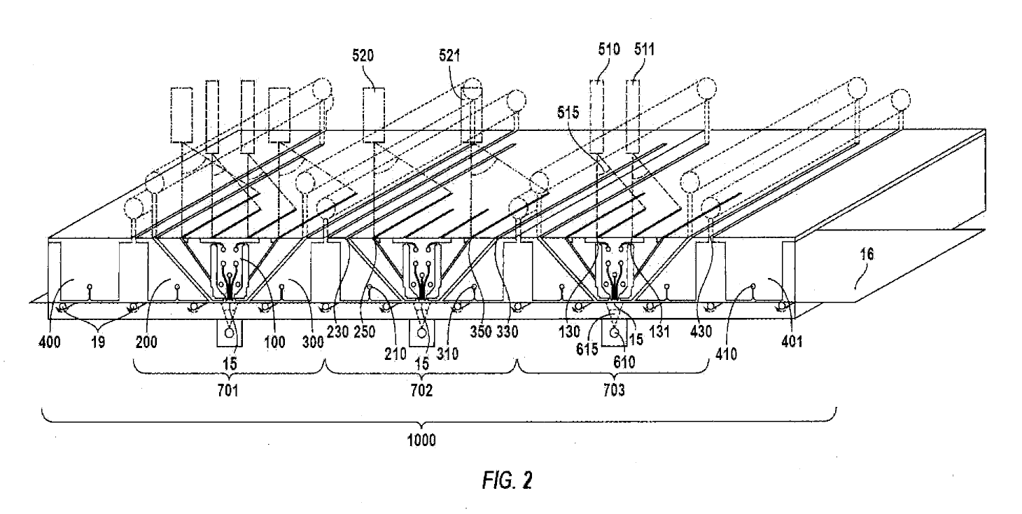

FIG. 2 is a schematic perspective view of a portion of an open in-line system 1000 having three sequential chamber assemblies 701, 702 and 703 used to deposit three similar or different thin film layers on substrates 16. Substrate 16, which may be a thin metal foil or other material, substantially absorbs the applied light beam energy until it reaches a sufficiently high temperature to form a thin film coating by thermal pyrolysis of the reactant gases. The substrate 16 can be continuously moved through deposition zones 15a, 15b and 15c using drive rollers 19 as guides. A substrate, such as substrate 16, enters and exits system 1000 via entry section 400 and exit section 401, respectively. The entry and exit sections are used to control the atmosphere within system 1000 and isolate it from the ambient. Although exemplary system 1000 is shown as including three chamber assemblies, it is understood that a system in accordance with embodiments of the present invention may have fewer or more than 3 chamber assemblies, e.g., 5 or 6.

It is also understood that any of the chamber assemblies may be used to deposit a film, heat treat or anneal the substrate, or heat treat or anneal a film deposited by other chambers. For example, in one operation, chamber assembly 701 may be used to remove moisture from the surface of the substrate 16 prior to deposition of a film layer using, e.g., chamber assembly 702. In another operation, chamber assembly 702 may be used to anneal a film layer deposited by chamber assembly 701, for example, to activate an in-situ dopant, prior to subsequent deposition of another film layer (that may be of the same or a different material) in chamber assembly 703. In one embodiment, the system may be heated above 100° C. to minimize moisture condensation, remove moisture from incoming substrates and expedite purging after ambient exposure due to system maintenance.

In FIG. 2, each chamber assembly 701, 702 and 703 includes an entry injector section 200, a center injector section 100 through which the chemical gases are delivered, and an exit injector section 300. Each entry injector section 200 has an inert chamber isolation gas inlet 210 which provides purge gas across the full width of its associated chamber to isolate that chamber from gases in the prior chamber or other sections of system 1000. Likewise, each exit injector section 300 has an inert chamber isolation gas inlet 310 which provides purge gas across the full width of its associated chamber to isolate that chamber from gases in the following chamber or other sections of system 1000. Similarly, the entry section 400 and exit section 401 each have an inert system isolation gas inlet 410 which provides purge gas across the full width of its associated section of the system to further isolate the first and last chamber assemblies 701 and 703 from external ambient gases.

Each chamber assembly 701, 702 and 703 may include at least three possible heating light sources. A first light source 610 may provide heating light to or through the substrate 16 to the film from underneath the substrate 16. A second light source 510 may be mounted so as to provide heating light through the entry injector light port 130 on the entry side of center injector section 100. A third light source 511 may be mounted so as to provide heating light through the exit injector light beam port 131 on the exit side of center injector section 100. In one exemplary embodiment, the first light source 610, second light source 510 and third light source 511 may each be a high power mercury gas discharge lamp, such as the Western Quartz 38-30013-C 300 W/in., 11,400 W, 950V, 13 A, 38.5″ Standard Mercury Lamp; the Western Quartz 38-20009-C 200 W/in., 7600 W, 950V, 8.8 A, 38.5″ Standard Mercury Lamp; or the Western Quartz M06-L31, 300 W/in., 6000 W, 650V, 10.3 A, 19.7″ Iron-Iodide Metal Halide Mercury Lamp which all emit UV radiation having large peaks in the range from 280 nm to 450 nm wavelength. In another exemplary embodiment, the first light source 610, second light source 510 and third light source 511 may be an array of high power UV LEDs, such as the PhlatLight UV CBT-120 which emit radiation centered at 380 nm or 400 nm wavelength. Other embodiments may use a laser for one or more of the light sources 610, 510 or 511, for example a high power UV laser.

Utilizing a gas discharge lamp 610 or an array of UV light emitting diodes (LEDs) as the light source 610 may provide a line source matching the full width of substrate 16 so that light beam 615 may easily be spread to heat the entire deposition zone 15 of its associated chamber assembly. A smaller light source 510 or 511 may also be spread across a predefined angle to heat the full width of the substrate 16. Even a light beam 515 from a laser source 510 or 511 may be swept across a predefined angle to heat the full width of the substrate. In the drawings, each light beam 515 is shown as being applied to one half of the deposition zone 15 of its associated chamber assembly on its respective entry and exit side of the center injector section 100.

For temperature measurement and control of the substrate 16 surface in each deposition zone 15, each chamber assembly has an associated entry infra-red pyrometer sensor 520 and an exit infra-red pyrometer sensor 521. Each entry infra-red pyrometer sensor 520 has an optical path passing through the entry infrared sensor port 250 to the surface of the substrate 16 in its associated deposition zone 15. Each exit infra-red pyrometer sensor 521 has an optical path passing through the exit infrared sensor port 350 to the surface of the substrate 16 in its associated deposition zone 15.

Gases, including reactive chemicals introduced to the deposition zone 15 through center injector sections 100, are exhausted through the entry chamber exhaust port 230 and exit chamber exhaust port 330 on each side of deposition zone 15. The inert purge gases introduced through the entry inert chamber isolation gas inlets 210, the exit inert chamber isolation gas inlets 310, and the inert system isolation gas inlets 410 are exhausted through the pressure equalization exhaust ports 430. Interconnection of the pressure equalization exhaust ports 430 allows for pressure equalization surrounding each deposition zone 15. Flow rate control of the gases supplied can be accomplished using mass flow controllers (MFCs) or other devices, as is well known in the art. Control of the exhaust flows can be achieved using methods applied in other atmospheric chemical vapor deposition systems as described, for example, in U.S. Pat. Nos. 4,834,020; 5,113,789; 6,143,080 and 6,761,770, the contents of all of which are incorporated herein by reference in their entirety.

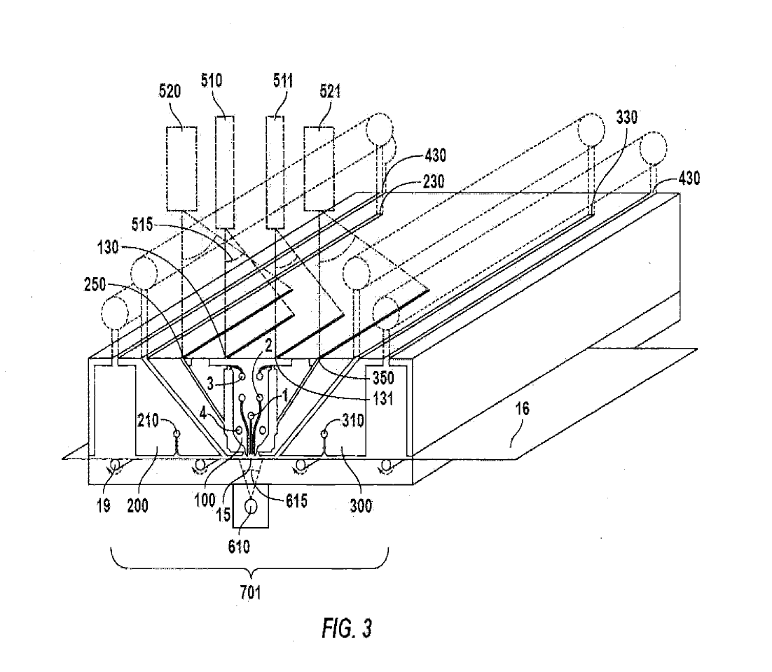

FIG. 3 is a magnified front perspective view of an interior cross section portion of chamber assembly 701. It is understood that chamber assemblies 702 and 703 are similar to chamber assembly 701. The chamber assemblies have a modular design so that they may be coupled to one another in any number with relative ease and simplicity to enable deposition of any desired stack of films. As shown, the pressure equalization exhaust ports 430 extend across the full width of the system. The entry chamber exhaust port 230 and exit chamber exhaust port 330 disposed on opposite sides of each deposition zone 15 extend the full width of substrate 16.

The entry infrared sensor port 250 and the exit infrared sensor port 350 allow for scanning the full width of the substrate 16 by infra-red pyrometer sensors 520 and 521. Light beam entry port 130 formed on the entry side of center injector section 100, and light beam exit port 131 formed on the exit side of center injector section 100 also allow spreading of the beam 515 across the full width of the substrate 16, particularly if light sources 510 and 511 cover less than the full width of the substrate. In the case of smaller substrates 16, such as 156 mm width as used for many solar cells, the entry and exit injector light beam ports 130 and 131 may be as small as simple circular openings of approximately 6 mm diameter or less. In the case of larger substrates 16, such as 0.6 m or 1 m width as used for many solar cell panels, the entry and exit injector light beam ports 130 and 131 may be elongated as shown in FIG. 3 to accommodate spreading the beam 515 to reach the full width of the substrate 16. If a laser is used as light source 510 or 511, the entry and exit injector light beam ports 130 and 131 may accommodate rastering or scanning the beam 515 to reach the full width of the substrate 16.

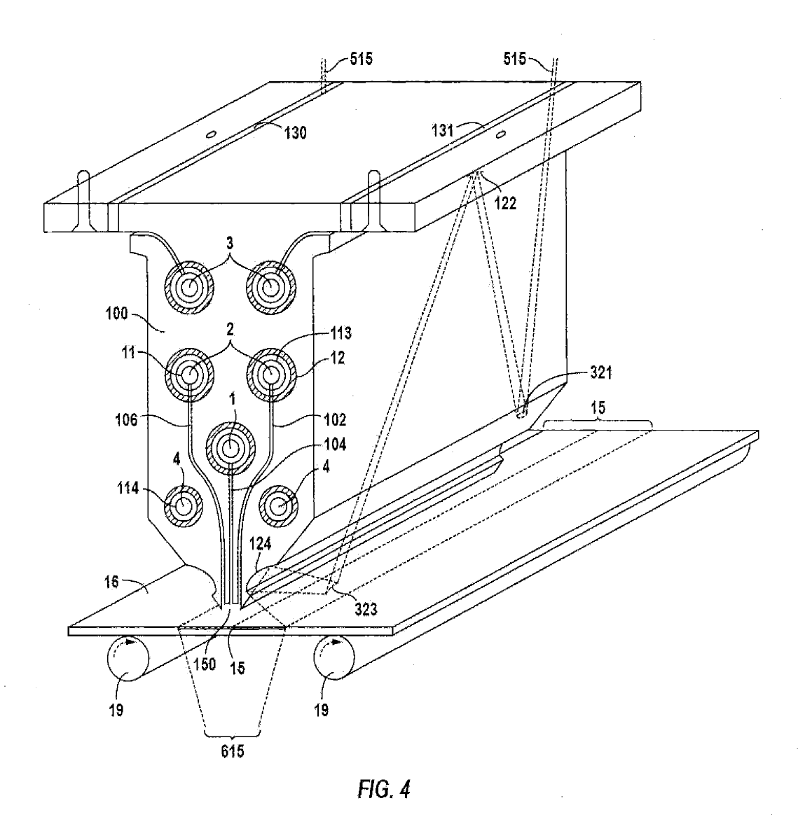

FIG. 3 also shows the location for injection of the gases supplied through the center injector section 100 to the injector gas outlet area 150, with greater detail shown in the magnified view of FIG. 4. Inert light beam path purge gas 3 supplies the entry injector light beam port 130 on the entry side of center injector section 100 and the exit injector light beam port 131 on the exit side of center injector section 100 with clean purge gas to prevent incursion or diffusion of reactive chemicals into the optical path of the light beams 515. The chemical gas source 1 includes the element or elements that are to be deposited on the substrate. The inert gas source 2 surrounds the chemical source gas 1 on each side so as to direct the desired reactive gases to substrate's surface for pyrolytic deposition. The temperature regulation gas or liquid 4 is circulated through the center injector section 100 to regulate and maintain the desired temperature of the chemical source gas 1 and inert source gas 2 within the center injector section 100 as they are delivered to the injector gas outlet area 150. For example, cooling the source gas 1 and inert source gas 2 within the center injector section 100 may be necessary for high surface deposition temperature to prevent pre-reaction of the chemical source gas 1 above the substrate 16 that could generate gas phase particulate formation.

As an exemplary embodiment of the present invention, FIG. 4 is a magnified perspective view of center injector section 100 of FIG. 3. The visible face of the center injector section 100 depicts the end of the center injector section 100 at the edge of the substrate 16, rather than the center of the system as shown in FIGS. 2 and 3. Each of the chemical source gas 1, inert source gas 2 and the inert light beam path purge gas 3 may be uniformly supplied across the width of the center injector section 100 in an injector metering tube 11. Each injector metering tube 11 is inserted within an injector gas plenum 113 which is a gun-drilled hole or path bored across the full width of the center injector section 100. A series of holes, slots or other openings (not shown) in each injector metering tube 11 is directed opposite the slots that feed the gases to the injector gas outlet area 150.

The chemical source gas inlet 104 is the slot that supplies the chemical source gas 1 to the injector gas outlet area 150. The entry inert source gas inlet 106 is the slot that uniformly supplies the inert source gas 2 to the injector gas outlet area 150 across the full width of the center injector section 100. The exit inert source gas inlet 102 is the slot that uniformly supplies the inert source gas 2 to the injector gas outlet area 150 across the full width of the center injector section 100. The temperature regulation gas or liquid 4 may be directly circulated through the injector cooling/heating plenum 114 which is also a gun-drilled hole or path bored across the full width of the center injector section 100. All of the injector gas plenums 113 may be sealed by injector O-ring seals 12 at the ends of the center injector section 100. The injector cooling/heating plenums 114 may be sealed in a similar fashion. The center injector section 100 with the gas plenums and metering tubes that distribute the injected gases uniformly across a substrate may be made using known industry manufacturing techniques, as described in U.S. Pat. Nos. 5,136,975; 5,683,516; 6,022,414; 6,200,389; 6,521,048 B2 and US Application No. 2003 0061991, the contents of which are incorporated herein by reference in their entirety. In some embodiments, the chamber assemblies are made from aluminum.

The operating temperature constraints upon O-ring seals and other elastomers are minimal in this invention compared to hot-wall reactor designs, giving more flexibility in the manufacturing design. For example, the injector of extended length may be made in sections and bolted together using O-ring seals or gaskets rather than requiring brazing or welding to withstand high operating temperatures. The injector gas outlet area 150 is in close proximity to the substrate 16 so that the chemical source gas 1 is delivered directly to the surface at a high concentration to yield efficient chemical conversion to the desired thin film material. The spacing between the chemical source gas inlet 104 at the injector gas outlet area 150 and the substrate 16 may typically be approximately 8 mm or less.

The deposition zone 15 may extend typically from 1 cm up to 4 cm in the direction of travel of the substrate 16 and match the width of the substrate across the system. Typical substrates may vary from 156 mm width up to 1 m width for solar panel applications. FIG. 4 shows the area of the deposition zone 15 extending across the entire substrate width. The deposition zone 15 may be heated to the desired temperature by three light sources, as shown, for example, in FIG. 3. The primary light source 610 applies light beam 615 to the side of the substrate opposite the injector and the reactive gases (i.e., to the bottom of the substrate as depicted) so that there is no photolytic interaction and the deposition occurs by thermal pyrolysis. The second and third light sources 510, 511 may simultaneously apply light beams to the same side of the substrate as the injector and the reactive gases (i.e., the top of the substrate as depicted) if needed or desired, for example, to reach a higher temperature or to minimize thermal stress and warpage to the substrate. The wavelength(s) of the second and third light sources may be selected to avoid photolytic interaction with the reactive gases as desired. The optical path of the light beam 515 through the exit injector light beam port 131 on the exit side of center injector section 100 to supply heat to the exit half of the deposition zone 15 is shown in FIG. 4. An equivalent optical path would occur for the light beam 515 through the entry injector light port 130 on the entry side of center injector section 100 to supply heat to the entry half of the deposition zone 15.

FIG. 4 shows how the optical path for the supplementary light beam 515 can be integrated into the injector in order to maintain a close spacing of the injector to the substrate for control of the gas flows. If the light sources 510, 511 cover less than the full width of the substrate 16, the light beam 515 may be spread to heat the full width of the substrate in the manner shown in FIG. 4. The light beam 515 is directed onto the convex polished mirror surface 321 on the exit injector section 300 (not shown), reflected in a greater solid angle to the concave polished mirror surface 122 on the center injector section 100, then reflected in a more parallel beam to the convex polished mirror surface 323 on the exit injector section 300 (not shown), then reflected at a wider solid angle into the concave polished mirror surface 124 on the center injector section 100, which directs the elongated beam through a narrow focal point where the inert light beam path purge gas 3 exits towards the substrate 16 and spreads out over 2 cm as depicted in FIG. 4 to cover half the deposition zone 15. A shorter gas discharge lamp or array of UV LEDs utilized as the supplementary light sources 510, 511 thus may be spread to cover the entire width of the substrate and the entire deposition zone illuminated by the first light source 610 without requiring an increased distance of the injector from the substrate surface. In the case of smaller substrates 16, such as 156 mm in width as used for many solar cells, the polished mirror surfaces alone may spread even a stationary light beam 515 used as the light source to the full 156 mm width deposition zone where a light beam 515 exits through a slightly diverging lens that yields a beam diameter of approximately 3 mm or more at the first reflecting polished minor surface 321. For larger substrates 16, such as 0.6 m or 1 m width as used for many solar cell panels, a narrow light beam 515, such as a laser, may be rapidly rastered or scanned to heat the full width of the substrate 16 as indicated by the arrows in FIG. 4.

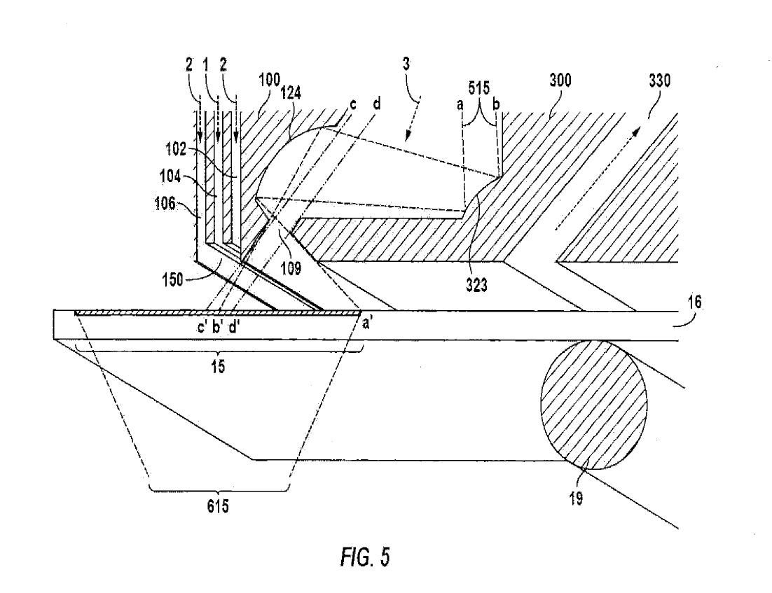

FIG. 5 is a magnified perspective view of a portion of a chamber assembly 701 incorporating all three light sources 610, 510 and 511 which includes deposition zone 15, the location where the source gases 1, 2 and 3 are injected at injector outlet area 150 and removed at exhaust port 330, in accordance with one exemplary embodiment of the present invention. Exemplary deposition zone 15 is shown in close proximity to three gas inlets 102, 104 and 106 that together form injector outlet area 150. Gas inlet 104, shown as being disposed between gas inlets 102 and 106, is used to inject a reactive gas 1 on the surface of the target surface. Gas inlets 102 and 106 are used to inject an inert gas 2 on the target substrate. The inert gas 2 is used to direct and spread the reactive gas 1 over the target deposition zone. The laser path purge gas 3 is injected through narrow opening 109 adjacent to the inert source gas port 106 and 102 on each side of the injector deposition area 150 in order to prevent source gas 1 chemicals from entering the area containing polished mirror surfaces 124 and 323. Exhaust port 330 is an outlet that receives and disposes of the injected gases 1, 2 and 3.

The light beam 515 is shown traversing a path from a to a′ and b to b′ in order to spread to cover half of the deposition zone 15, as shown by the distance a′ to b′. The light beam 515 is reflected off a convex polished mirror surface 323 on exit injector section 300 to a concave polished mirror surface 122 on the center injector section 100 which focuses the light beam through the narrow opening 109 and then spreads it between points a′ and b′ on the substrate surface. In some embodiments, the width of the laser beam between points a′ and b′ may vary. In one embodiment, the distance a′b′ may vary from 1 cm to 2 cm. The light beam 615 positioned opposite the center injector section 100 illuminates the entire deposition zone 15. The temperature of the substrate 16 within the deposition zone 15 is visible between points c′ and d′ by the infrared sensor 521 via the path shown from points c to c′ and d to d′.

Utilizing the natural convection flow of the chemical gases heated by impingement upon the hot substrate 16 surface in the deposition zone 15 may enhance the deposition rate and chemical conversion efficiency. In some embodiments, the injectors may be positioned below the substrate that would be visible in an inverted view of the current drawings (not shown). Accordingly, in such embodiments (not shown), the gas flows upward against the hot bottom surface of the substrate. In such embodiments, the substrate driver rollers may be located at the edges of the substrate to move the substrates through the deposition zones.

In accordance with one exemplary embodiment of the present invention, silicon is deposited on a substrate at high surface temperature ranging from 800° C. to 1000° C. to yield a large grain size multi-crystalline film suitable for photovoltaic applications. Commonly used hydride gases, such as silane (SiH₄) or disilane (Si₂H₆) may be used to deposit silicon at atmospheric pressure. Inert gases such as nitrogen (N₂), argon (Ar), or helium (He) may be used to dilute the hydride gas and to supply additional isolation and purge flow so as to separate any oxygen (O₂) that may be present from the reactant gases and that would otherwise cause SiO₂ to form. In-line gas purifiers may also be used to reduce any oxygen (O₂) or moisture (H₂O) contamination, for example, to levels below 50 ppb in the critical gas paths to prevent oxidation of the hydride gas.

Multiple sequential depositions may be used to form a sufficiently thick multi-crystalline silicon layer suitable for absorption of sunlight. The desired doping of the sequential layers to form a P-i-N junction in-situ may be achieved by introduction of dopant gases such as Phosphine (PH₃), Diborane (B₂H₆) or Germane (GeH₄) mixed in the appropriate ratio with the silicon precursor. For example, a suitable substrate may be first deposited with a thin layer of approximately 0.3 μm of phosphorus doped Si to form an N-type donor layer, then deposited with a thick layer of at least 5.0 μm of undoped Si to form an intrinsic absorber layer, then deposited with a thin layer of approximately 0.3 μm of boron doped Si to form a P-type donor layer.

The deposition temperature and the substrate surface area receiving the light beam may be varied in accordance with the thermal properties of the substrate. A suitable substrate which would sufficiently absorb UV illumination from a mercury gas discharge lamp or UV LEDs to reach 800° C. to 1000° C. for silicon deposition might be a thin metal foil of approximately 50 μm thickness. Various composition metal foils might be suitable, such as one made primarily of Nickel or Nickel doped with Tungsten or other metals. Additional properties of the substrate may be selected to enhance the desired deposition, such as using a RaBITs textured surface to promote the crystalline structure of the deposited film. For example, the light beam may be spread over a 4 cm width by 1 m length or concentrated to a 1 cm width by 1 m length for processing 1 in wide substrate panels. The same illumination power when applied to a narrower deposition area can increase the substrate surface temperature and thus provide a higher deposition rate to counteract losses in throughput. In the exemplary embodiment shown in FIG. 4, the light source positioned on each side of the injector assembly covers an area that is, for example, 2 cm wide and 1 m long. Therefore, each deposition zone covers an area that is 4 cm wide and 1 m long.

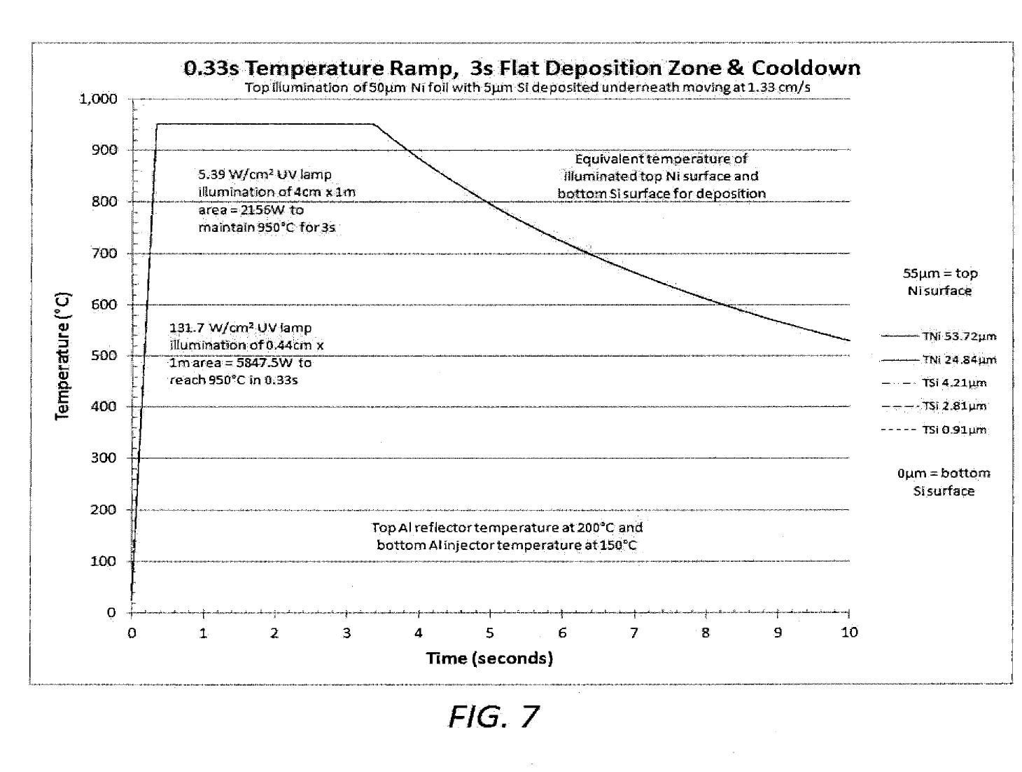

In one embodiment, to achieve a silicon deposition rate of 0.33 μm/second, a temperature of approximately 950° C. may be used over a deposition zone of 4 cm width by 1 m length. Then, a 3 second exposure may be used to deposit a silicon layer that is 1 μm in thickness, thus yielding a continuous throughput of substantially 48 m²/hour. Multiple sequential chambers may be used to yield greater silicon total thickness at the same throughput. At a chemical conversion efficiency of 40% and a flow rate of 1.86 slm, Si₂H₆ may be used. With dilution by inert gases to approximately 10 liters per minute (slm) yielding uniform metering backpressure in each injector port, and by using the same flow to purge each of the adjacent optical paths, the partial pressure of Si₂H₆ in the deposition zone may be approximately 28 Torr in an atmospheric pressure chamber. Commercially available standard mercury gas discharge lamps have sufficient power to preheat and maintain at temperature the 4 cm by 1 m area of a 50 μm thick Nickel foil deposited with silicon in the deposition zone. For example, four Western Quartz 38-30013-C, 300 W/in., 11,400 W, 950V, 13 A, 38.5″ Standard Mercury Lamps would preheat the Nickel foil in 0.33 seconds over a 0.44 cm-by-1 m area. Two of the same type of lamps positioned on the side of the substrate opposite the injector would maintain the 950° C. temperature over the 4 cm by 1 m area of deposition, assuming 10.5% conversion to radiant energy in the 280 nm to 400 nm spectrum. Suitable reflectors made of polished aluminum or similar material, positioned around the UV lamps to redirect the first reflection from the substrate back to the deposition zone area, can reduce the total power required. The actual power required to preheat the substrate for sequential chambers would also be reduced since the Nickel foil substrate would not cool completely back down to room temperature between chambers. Alternatively, an array of PhlatLight UV CBT-120 LEDs each emitting over a 12 mm² area and having approximately ten times the rated life of the mercury vapor gas discharge lamps could be used, with approximately 394 LEDs positioned for preheating and 167 LEDs positioned for maintaining the 950° C. temperature in the deposition zone. The illumination power required to heat a 50 μm thick Nickel foil having 5 μm deposited silicon on the opposite side in 0.33 seconds and maintain a temperature of 950° C. for 3 seconds was calculated by numerical model simulation and the results plotted in FIG. 7. The FIG. 7 simulation also shows that the heat transfer through the Nickel foil to the silicon film is fast enough that no difference in temperature across the substrate is maintained even though the UV light is absorbed near the surface of the Nickel foil. In some embodiments, a second and third light source may positioned on the same side of the substrate as the deposited film and utilized to increase the deposition temperature up to a maximum of 1200° C., just below the melting point of silicon. Alternatively, the second and third light sources may be utilized to reduce the power needed from the primary light source 610 underneath the substrate. Additionally, by supplying heat to both sides of the substrate, thermal stress on the substrate is minimized and the deposited film can also be, annealed at a high temperature.

In-situ doping of the silicon deposition can be accomplished by injecting a dopant gas mixed with the silicon source gas in approximately the same ratio as desired for incorporation in the deposited film. For example, if a doping level of approximately 1×10²⁰ atoms/cc of phosphorous (P) is desired in the deposited silicon film, which contains approximately 5.0×10²² atoms/cc, then a mixture of approximately 0.2% PH₃ in PH₃ and SiH₄ may be injected, taking into account variations in incorporation rates with temperature. If Si₂H₆ is used as the silicon source gas, then a ratio of PH₃ to the sum of the PH₃ and twice the Si₂H₆ equal to 0.2% may be used. For example, if 1.86 slm Si₂H₆ is being injected, adding approximately 7.5 sccm of PH₃ can yield an N-type silicon doped with approximately 1×10²⁰ atoms/cc of phosphorus. Diluted mixtures of hydride gases in an inert gas are readily available for easy control of low flow rates for low doping levels.

To enhance the quality of the deposited film, in-line annealing may be performed by similar light beams as used to deposit the film. After passing through one deposition zone and while traveling at a nearly constant speed, the substrate passes through another deposition zone which does not inject reactive gases but emits light beams. In such a deposition zone, the emitted light beams are used to anneal the previously deposited film. For a multi-layer stack of silicon films, annealing may be used to increase the crystalline grain size of the deposited film or to activate the in-situ dopant to increase conductivity of a specific deposited layer without excess diffusion of the dopant. Other materials besides silicon can be deposited as well, in-situ in-line in separate sequential chambers of one system if desired. In accordance with another embodiment of the present invention, silicon oxide is deposited on a substrate at high surface temperature ranging from 700° C. to 1000° C. A single chemical precursor containing oxygen and silicon such as tetraethylorthosilicate (TEOS) can be injected to react by thermal pyrolysis to yield a high quality silicon oxide film that, for example, could act as a passivation layer in a photovoltaic device. In another embodiment of the present invention, silicon nitride is deposited on a substrate at high surface temperature ranging from 750° C. to 1000° C. by injecting gases containing nitrogen and silicon such as SiH₄ or Si₂H₆ and NH₃ which could act, for example, as an anti-reflection coating (ARC) in a photovoltaic device.

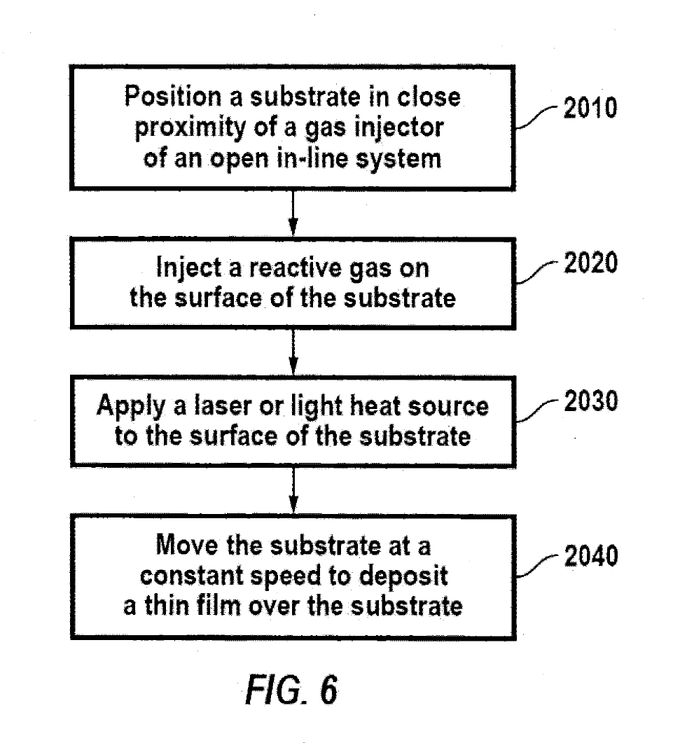

FIG. 6 is a flowchart of steps used to deposit a thin film on a substrate, in accordance with one exemplary embodiment of the present invention. The substrate is brought 2010 to close proximity of a multitude of gas injectors of a thin film deposition system. As the substrate is moved horizontally along a predefined direction, it is injected 2020 with reactive gases and pyrolytically heated with a heating light source 2030 focused on either the substrate surface in contact with the flowing gases or the opposite substrate surface. The heating light source has a wavelength selected so as to be absorbed substantially by the substrate or the deposited film layer. Accordingly, as the substrate moves 2040 along the horizontal direction, a layer of film having a substantially uniform thickness is deposited over the surface of the substrate. The deposited film includes an element included in the reactive gases.

The above embodiments of the present invention are illustrative and not limitative. Various alternatives and equivalents are possible. The invention is not limited by the reactive gas, inert gas, isolation gas, and the like used during film deposition or annealing. The invention is not limited by the type of substrate or the film being deposited or annealed. The invention is not limited by the type or the wavelength of the heating light source. The invention is not limited by the number of chamber assemblies nor by the optical path of the light beam directed on the substrate during either film deposition or annealing. The invention is not limited by the rate used to deposit a film nor by the number of different layers that may be deposited on a substrate. Other additions, subtractions or modifications are obvious in view of the present disclosure and are intended to fall within the scope of the appended claims.

What is claimed is:

1. An apparatus adapted to deposit a thin film on a substrate comprising:
a two-sided substrate, a gas injector, a heating light source, an inert gas inlet and an exhaust port;
wherein said heating light source is positioned on one side of said substrate to heat said substrate;
wherein said gas injector is positioned on the other side of said substrate to deposit a thin film of reactive gas onto said substrate when said gas injector is in close proximity to said substrate and said substrate is heated by said heating light source;
wherein said inert gas inlet places a curtain of inert gases around said reactive gases to prevent introduction of impurities into said deposition; and,
wherein said exhaust port removes excess reactive gases and inert gases.

2. The apparatus of claim 1 further comprising an additional heating light source on the same side of said substrate as said gas injector.

3. The apparatus of claim 1 wherein said deposition takes place in an open in-line system wherein inert gas passing through said inert gas inlet isolates the deposition from ambient conditions.

4. The apparatus of claim 1 wherein said heating light source is a gas discharge lamp.

5. The apparatus of claim 4 wherein said gas discharge lamp is a high power mercury gas discharge lamp.

6. The apparatus of claim 1 wherein said substrate is a thin metal foil comprised primarily of nickel which is heated to a temperature of approximately 700° C. to 1000° C.

7. The apparatus of claim 2 wherein said heating light sources are selected from the group consisting of gas discharge lamps, light emitting diodes (LEDs) and lasers.

8. The apparatus of claim 1 wherein said deposition is a pyrolytic deposition.

9. The apparatus of claim 1 further comprising a conveyor to hold said substrate and move it as said thin film deposition is occurring.

10. An apparatus adapted to deposit a thin film on a substrate comprising:
a reaction chamber having a two-sided substrate, a substrate conveyor, a gas injector, a heating light source, an inert gas inlet and an exhaust port;
wherein said conveyor conveys said substrate through said reaction chamber until it is in close proximity to said gas injector and said heating light source;
wherein said heating light source is positioned on one side of said substrate to heat said substrate;
wherein said gas injector is positioned on the other side of said substrate to deliver at least one reactive gas onto said substrate to deposit a thin film by thermal pyrolysis when said gas injector is in close proximity to said substrate and said substrate is heated by said heating light source;
wherein said inert gas inlet places a curtain of inert gases around said reactive gases to prevent introduction of impurities into said deposition; and,
wherein said exhaust port exhausts both excess reactive gases and inert gases from said chamber.

11. The apparatus of claim 10 further comprising an additional heating light source on the same side of said substrate as said gas injector.

12. The apparatus of claim 10 wherein said deposition takes place in an open in-line system wherein inert gas passing through said inert gas inlet isolates the deposition from ambient conditions.

13. The apparatus of claim 10 wherein said heating light source is a gas discharge lamp.

14. An apparatus adapted to deposit a thin film on a substrate comprising:
a plurality of connected reaction chambers each having a gas injector and a heating light source;
a substrate conveyor capable of conveying a two-sided substrate between said connected reaction chambers so that reactive gases can be sequentially deposited onto said substrate or said substrate can be annealed in said chambers;
wherein in each said reaction chamber said conveyor conveys said substrate through said reaction chamber until it is in close proximity to said gas injector and said heating light source;
wherein said heating light source is positioned on one side of said substrate to heat said substrate;
wherein said gas injector is positioned on the other side of said substrate to deliver at least one reactive gas onto said substrate to deposit a thin film by thermal pyrolysis when said gas injector is in close proximity to said substrate and said substrate is heated by said heating light source;
wherein said inert gas inlet places a curtain of inert gases around said reactive gases to prevent introduction of impurities.

15. A method of depositing a thin film onto a substrate comprising:
placing a substrate between a heating light source and a gas injector;
heating said substrate with said heating light source;
using said gas injector to deliver reactive gases onto said substrate to deposit a thin film by thermal pyrolysis when said substrate is in close proximity to said gas injector and when said substrate has been heated by said heating light source; and,
surrounding said reactive gases with inert gases to prevent introduction of impurities into said deposition.

16. The method of claim 15 wherein said substrate is also heated by an additional heating light source on the same side of said substrate as said gas injector.

17. The method of claim 15 wherein said deposition takes place in an open in-line system wherein said inert gases isolate the deposition from ambient conditions.

18. The method of claim 15 wherein said heating light source is a gas discharge lamp.

19. The method of claim 15 wherein said gas discharge lamp is a high power mercury gas discharge lamp.

20. The apparatus of claim 16 wherein said heating light sources are selected from the group consisting of gas discharge lamps, light emitting diodes (LEDs) and lasers.

21. An open in-line system adapted to deposit a thin film on a surface of a substrate, the apparatus comprising:
a substrate holder adapted to hold the substrate;
a first gas injector adapted to inject at least one reactive gas to a predefined surface area of the substrate exceeding 10 cm² to form a first film;
a first light source selected from the group consisting of a gas discharge lamp, light emitting diode or laser, adapted to concurrently apply a first light beam including one or more wavelengths absorbed substantially by the substrate or film and substantially reflected by the injector and walls of the system to heat the substrate opposite said predefined substrate surface area to a high temperature suitable for pyrolytic deposition of a first film at a high rate without photolytic interaction on said predefined surface area and without substantial pyrolytic or photolytic deposition on the injector or walls of the system, said first film comprising an element included in the reactive gas;
a chamber adapted to receive said substrate during the thin film deposition, said chamber having a pressure at or near atmospheric pressure and further adapted to receive the at least one reactive gas being applied to said predefined surface area of said substrate for pyrolytic deposition of said first film;
first and second gas inlets adapted to supply an inert isolation gas for isolating the chamber from external ambient gases during the thin film deposition such that a reducing atmosphere can be maintained in said chamber so said first film can be a metal or nitride rather than be limited to oxides, said first and second gas inlets being positioned along opposing sides of the gas injector;
a first exhaust port disposed between said first gas inlet and said gas injector and adapted to exhaust a first portion of both the residual reactive gases and isolation gas from the chamber; and
a second exhaust port disposed between said second gas inlet and the first gas injector and adapted to exhaust a second portion of the residual reactive gases and isolation gas from the chamber.
one or more moving means adapted to move the substrate at a substantially constant speed relative to the first gas injector to achieve a substantially continuous deposition of a substantially same thickness of the film over a predefined surface area of the substrate.

22. The open in-line system of claim 21 wherein said first gas injector is disposed to inject within said chamber a continuous line source of at least one said reactive gas as a laminar flow in a direction substantially perpendicular to the direction of travel of said substrate, exhausting at least one said reactive gas on each side, and controlled in temperature to prevent internal pre-reaction of said first reactive gas and minimize deposition of the film on the exposed surfaces in the chamber.

23. The open in-line system of claim 21 further comprising:
mirror-like reflective surfaces adjacent to said first light source positioned and shaped so as to capture the reflection of the applied light beam from said substrate and reapply the reflected light beam to said substrate for more efficient heating.

24. The open in-line system of claim 21 wherein said first light source is comprised of a gas discharge lamp and said substrate is a thin metal foil comprised of a nickel material which substantially absorbs UV light.

25. The open in-line system of claim 21 wherein said first light source is comprised of an array of high power ultraviolet light emitting diodes emitting wavelengths at or near 380 nm to 400 nm and said substrate is a thin metal foil which substantially absorbs ultraviolet light.

26. The open in-line system of claim 21 further comprising:
a second gas injector injecting a second reactive gas to the surface of the substrate in a second chamber positioned adjacent to said chamber and configured with gas inlets and exhaust ports, said one or more moving means further adapted to move the substrate at a substantially constant speed relative to the first gas injector to position the substrate in close proximity of said second gas injector; and
a second light source adapted to apply a second light beam to the substrate opposite the second gas injector to provide heat for pyrolytic deposition of a second film on the substrate surface.

27. The open in-line system of claim 26 wherein said first and second films include a similar material.

28. The open in-line system of claim 26 wherein said first and second films include different materials.

29. The open in-line system of claim 26 wherein a second light source applies a second light beam through an inert gas purged optical path integrated within said first gas injector so it is coincident with said first reactive gas on the surface of said substrate in said predefined surface area for deposition, utilizing mirror-like surfaces within said first gas injector composed of a substantially reflective material so that the substrate and film are heated from both sides to a high temperature suitable for pyrolytic deposition.

30. The open in-line system of claim 29 further comprising:
a third light source which applies its light beam through a second inert gas purged optical path integrated within said first gas injector so it is coincident with said first reactive gas on the surface of said substrate in said predefined surface area for deposition, utilizing mirror-like surfaces within said first gas injector composed of a substantially reflective material such that said second and third light sources apply their light beams in a symmetric fashion on each side of said line source laminar flow injection of said reactive gas, allowing heating of said predefined surface area of said substrate with minimal spacing between said first gas injector and said substrate to control gas flow for uniform deposition.

31. The open in-line system of claim 21 wherein said one or more moving means is adapted to transport said substrate in an orientation so as to enable said first gas injector to apply said reactant gases to a bottom surface of said substrate to enable said first film to be deposited on the bottom surface of said substrate.

32. The open in-line system of claim 21 further comprising:
third and fourth exhaust ports spaced away from said first and second gas inlets and adapted to provide exhaust paths for third and fourth portions of said isolation gas from said chamber; and
third and fourth gas inlets spaced away from said third and fourth exhaust ports and adapted to supply isolation gas for further isolating the chamber from external ambient gases during the film deposition.

33. The open in-line system of claim 21 wherein said first and second gas inlets are disposed symmetrically with respect to said gas injector and at a first distance from said gas injector, and wherein said first and second gas exhaust ports are disposed symmetrically with respect to said gas injector and at a second distance from said gas injector, said second distance being smaller than said first distance.

34. The open in-line system of claim 21 further comprising:
one or more additional chambers positioned adjacent to the first chamber configured with gas injectors, gas inlets and exhaust ports for injecting and exhausting additional gases, said one or more moving means further adapted to move the substrate at a substantially constant speed through all the sequential adjacent chambers; and
additional light sources adapted to apply light beams to the substrate opposite the gas injectors to provide heat for pyrolytic deposition of additional films on the substrate surface or for annealing the film or substrate.

35. The open in-line system of claim 34 wherein the films deposited in the sequential adjacent chambers include one or more different materials acting as a barrier layer, absorber layer, transparent conductive oxide (TCO) layer, anti-reflective coating (ARC) layer, or passivation layer which are suitable for comprising layers of a photovoltaic device,

36. The open in-line system of claim 21 wherein said reactive gas includes silicon atoms and said deposited film is selected from a group consisting of amorphous, micro-crystalline, poly-crystalline, multi-crystalline, and epitaxial crystalline silicon film in a temperature range from 550° C. to 1200° C.

37. The open in-line system of claim 36 wherein said reactive gas is selected from a group consisting of SiH₄, Si₂H₆, Si₃H₈ and silicon hydride gases.

38. The open in-line system of claim 21 wherein said at least one reactive gas further comprises a dopant and wherein said deposited film includes a layer doped with the dopant.

39. The open in-line system of claim 38 wherein said dopant is selected from a group consisting of PH₃, B₂H₆, GeH₄ and hydride gases.

40. The open in-line system of claim 26 wherein said second light source is further adapted to anneal the deposited film.

41. The open in-line system of claim 34 wherein said first deposited film comprises a first dopant of a first conductivity type, said first reactive gas comprising the first dopant, and wherein said second deposited film comprises a second dopant of a second conductivity type, said second reactive gas comprising the second dopant, said first and second doped film layers comprising a semiconductor p-n junction or n-p junction.

42. The open in-line system of claim 41 further comprising:
a third gas injector injecting a third reactive gas on the surface of the substrate; and
a third light source adapted to apply a third light beam to the substrate opposite the third gas injector surface to provide heat for pyrolytic deposition of a third film on the substrate surface, wherein said third film comprises an undoped intrinsic layer to form a semiconductor p-i-n junction or n-i-p junction.

43. The open in-line system of claim 42 wherein said reactive gases from said first, second and third injectors include silicon atoms, and wherein said deposited first, second and third films are selected from a group consisting of amorphous, micro-crystalline, poly-crystalline, multi-crystalline, and epitaxial crystalline silicon films deposited in a temperature range from 550° C. to 1200° C.

44. The open in-line system of claim 21 wherein said at least one reactive gas includes silicon and nitrogen and said deposited film is silicon nitride.

45. The open in-line system of claim 21 wherein said at least one reactive gas includes silicon and oxygen and said deposited film is silicon dioxide.
